(19) United States
(12) Patent Application Publication
(10) Pub. No.: US 2026/0299652 A1
(43) Pub. Date: Oct. 1, 2026

(54) TOGGLE CLAMP QUICK DISCONNECT HINGE FOR ADDED COMPUTER-RELATED COMPONENT

(71) Applicant: Lenovo (United States) Inc., Morrisville, NC (US)

(72) Inventors: Bryan Binda, Morrisville, NC (US); Jean J. Xu, Morrisville, NC (US)

(21) Appl. No.: 19/096,535

(22) Filed: Mar. 31, 2025

(51) Int. Cl. G06F 1/18

(52) U.S. Cl. CPC G06F 1/181

(57) ABSTRACT

In one aspect, an apparatus includes a computer chassis that has a first opening at an upper portion and a second opening at a lower portion. The apparatus also includes a first toggle clamp for coupling to the computer chassis via the first opening, and a first mount for coupling the first toggle clamp to the computer chassis via the first opening. The apparatus further includes a second toggle clamp for coupling to the computer chassis via the second opening, and a second mount for coupling the second toggle clamp to the computer chassis via the second opening. In some examples, the apparatus also includes at least one computer-related component to which the first and second toggle clamps are couplable for the at least one computer-related component to rotate about a hinge established by the first and second toggle clamps as coupled to the computer chassis.

### FIELD

The disclosure below relates to technically inventive, non-routine solutions that produce concrete technical improvements. In particular, the disclosure below relates to assemblies with toggle clamps that establish a hinge for coupling one or more components to a chassis.

### BACKGROUND

As recognized herein, it can be desirable to connect computing components to the rear of a computer chassis on-the-fly without altering the chassis itself. However, the disclosure below recognizes that existing solutions are inadequate to enable such on-the-fly attachment in a quick and easy manner.

### SUMMARY

Accordingly, in one aspect an apparatus includes a computer chassis that has a first opening at an upper portion of the computer chassis and a second opening at a lower portion of the computer chassis. The apparatus also includes a first toggle clamp for coupling to the computer chassis via the first opening, and a first mount for coupling the first toggle clamp to the computer chassis via the first opening. The apparatus further includes a second toggle clamp for coupling to the computer chassis via the second opening, and a second mount for coupling the second toggle clamp to the computer chassis via the second opening. The apparatus also includes at least one computer-related component to which the first and second toggle clamps are couplable for the at least one computer-related component to rotate about a hinge established by the first and second toggle clamps as coupled to the computer chassis.

In some example embodiments, the coupling of the first toggle clamp to the computer chassis via the first mount, and the coupling of the second toggle clamp to the computer chassis via the second mount, may establish a vertical axis of rotation for the at least one computer-related component to rotate about the hinge.

Also in some example embodiments, the upper and lower portions of the computer chassis may be adjacent to the rear of the computer chassis.

What's more, in some implementations the at least one computer-related component may include a radiator, though it might additionally or alternatively include a graphics processing unit (GPU) or other type of computing component. Also if desired, the apparatus may include a personal computer housed within the computer chassis.

In addition, in some instances the first and second openings may define respective first and second handles of the computer chassis. Here, the first mount may be configured to attach to the first handle, and the second mount may be configured to attach to the second handle.

Still further, in some example embodiments the first mount may include a third opening into which a first post of the first toggle clamp is extendable to couple the first toggle clamp to the computer chassis with the first mount already engaged with the computer chassis. Also according to these embodiments, the second mount may include a fourth opening into which a second post of the second toggle clamp is extendable to couple the second toggle clamp to the computer chassis with the second mount already engaged with the computer chassis. Thus, the first toggle clamp may be manipulable to place the first toggle clamp into an extended position in which the first post extends into the third opening, and the second toggle clamp may be manipulable to place the second toggle clamp into an extended position in which the second post extends into the fourth opening.

In another aspect, an apparatus includes a chassis that has a first opening and a second opening. The apparatus also includes a first toggle clamp for coupling to the chassis via the first opening, and a first mount for coupling the first toggle clamp to the chassis via the first opening. The apparatus further includes a second toggle clamp for coupling to the chassis via the second opening, and a second mount for coupling the second toggle clamp to the chassis via the second opening.

In some example embodiments, the apparatus may also include at least one component to which the first and second toggle clamps are couplable for the at least one component to rotate about a hinge established by the first and second toggle clamps as coupled to the chassis.

In some instances, the chassis may be a computer chassis.

Also in some instances, the first mount may include a third opening into which a first post of the first toggle clamp is extendable to couple the first toggle clamp to the chassis with the first mount already engaged with the chassis, and the second mount may include a fourth opening into which a second post of the second toggle clamp is extendable to couple the second toggle clamp to the chassis with the second mount already engaged with the chassis. So here, the first toggle clamp may be manipulable to place the first toggle clamp into an extended position in which the first post extends into the third opening, and the second toggle clamp may be manipulable to place the second toggle clamp into an extended position in which the second post extends into the fourth opening.

In still another aspect, a kit includes a first mount for coupling a first clamp to a chassis via a first opening on the chassis to establish part of a hinge. The kit also includes the first clamp itself. The kit further includes a second mount for coupling a second toggle clamp to the chassis via a second opening to establish part of the hinge. In addition, the kit further includes the second clamp itself.

If desired, the kit may even include the chassis and a computer housed within the chassis.

Also if desired, the first clamp and the second clamp may be toggle clamps, though other types of clamps may also be used.

What's more, in some instances the kit may include at least one component to which the first and second clamps are couplable for the at least one component to rotate about the hinge established by the first and second clamps as coupled to the chassis. In one specific example, the at least one component may include a radiator.

### BRIEF DESCRIPTION OF THE DRAWINGS

The details of present principles, both as to their structure and operation, can best be understood in reference to the accompanying drawings, in which like reference numerals refer to like parts, and in which:

FIG. 1 is a block diagram of an example computer system consistent with present principles;

FIG. 2 shows a rear perspective view of a workstation computer as housed within a computer chassis consistent with present principles;

FIG. 3A shows a radiator as positioned within a rear opening of the computer chassis consistent with present principles;

FIG. 3B demonstrates that the radiator, when attached to the chassis via toggle clamps, can swing open about a hinge axis to allow access to computing components within the chassis consistent with present principles;

FIGS. 4A and 4B respectively show lower and upper perspective views of a rear chassis opening and chassis handle consistent with present principles;

FIG. 5 shows a schematic of upper and lower mounts that may be coupled to the handles of the chassis to interface with upper and lower toggle clamps for coupling a computing component to the chassis consistent with present principles;

FIG. 6 shows the toggle clamps apart from the chassis in perspective view and also shows the toggle clamps as extending their posts through chassis mounts to couple the computing component to the chassis consistent with present principles;

FIG. 7 shows an upper perspective view of an example mount for coupling a computing component to a computer chassis using toggle clamps consistent with present principles;

FIG. 8 shows a top perspective view of the example mount consistent with present principles;

FIG. 9 shows a bottom perspective view of the example mount consistent with present principles;

FIG. 10 shows a side perspective view of the example mount consistent with present principles;

FIG. 11 show a perspective view of an example mount as partially engaged with a computer chassis handle consistent with present principles; and

FIGS. 12 and 13 show perspective views of the example mount as fully engaged with the computer chassis handle consistent with present principles.

### DETAILED DESCRIPTION

Among other things, the detailed description below sets forth toggle clamp-based quick-disconnect hinges for attaching and detaching external desktop radiators and other computing components to/from a desktop computer chassis. Other example computing components might include a graphics processing unit (GPU), other peripheral cards, an extra storage drive (e.g., solid state drive or hard disk drive), etc.

Thus, in one aspect, present principles provide an ergonomic system to mechanically attach a radiator assembly (or other component) to the back a Lenovo P8 chassis or other type of computer chassis so that the radiator assembly can hinge open for access to the rear input/output (I/O) of the chassis. The use of toggle clamps obviates the constraints of other types of hinges, allowing the radiator to be easily attached to the base chassis by hand without the need for additional tools like screwdrivers and wrenches to do so.

Accordingly, in one aspect, push-pull toggle clamps may be used as quick disconnect hinges. This is then combined with chassis mounts that, once installed on the handles of the chassis, might have a single degree of freedom prior to engagement with the toggle clamps. Then, the clamping force from the installation of the push-pull toggle clamp hinges restrains the last degree of freedom of the mounts so that the mounts are rigidly fixed to the chassis, which in turn enables the hinging motion of the radiator assembly about the chassis using the toggle clamps.

Various mechanically-actuated components are therefore described below for enabling quick-disconnect hinges for a rear-attached, liquid cooling radiator. The hinge advantageously bears load in the axial direction to both fix the radiator in place axially and enable single-part assembly to the chassis handles. Thus, the use of toggle clamps as quick-release fastening devices can be used for hinges consistent with present principles, bearing axial load while still allowing the radiator assembly to hinge about the chassis once the clamps are mounted to the radiator itself.

Prior to delving further into the details of the instant techniques, note with respect to any computer systems discussed herein that a system may include server and client components, connected over a network such that data may be exchanged between the client and server components. The client components may include one or more computing devices including televisions (e.g., smart TVs, Internet-enabled TVs), computers such as desktops, laptops and tablet computers, so-called convertible devices (e.g., having a tablet configuration and laptop configuration), and other mobile devices including smart phones. These client devices may employ, as non-limiting examples, operating systems from Apple Inc. of Cupertino CA, Google Inc. of Mountain View, CA, or Microsoft Corp. of Redmond, WA. A Unix® or similar such as Linux® operating system may be used, as may a Chrome or Android or Windows or macOS or iOS operating system. These operating systems can execute one or more browsers such as a browser made by Microsoft or Google or Mozilla or another browser program that can access web pages and applications hosted by Internet servers over a network such as the Internet, a local intranet, or a virtual private network.

As used herein, instructions refer to computer-implemented steps for processing information in the system. Instructions can be implemented in software, firmware or hardware, or combinations thereof and include any type of programmed step undertaken by components of the system; hence, illustrative components, blocks, modules, circuits, and steps are sometimes set forth in terms of their functionality.

A processor may be any single-or multi-chip processor that can execute logic by means of various lines such as address lines, data lines, and control lines and registers and shift registers. Moreover, any logical blocks, modules, and circuits described herein can be implemented or performed with a system processor such as a central processing unit (CPU), a graphics processing unit (GPU), a neural processing unit (NPU), a digital signal processor (DSP), a field programmable gate array (FPGA) or other programmable logic device such as an application specific integrated circuit (ASIC), discrete gate or transistor logic, discrete hardware components, or any combination thereof designed to perform the functions described herein. A processor can also be implemented by a controller or state machine or a combination of computing devices. Thus, the methods herein may be implemented as software instructions executed by a processor, suitably configured application specific integrated circuits (ASIC) or field programmable gate array (FPGA) modules, or any other convenient manner as would be appreciated by those skilled in the art. Where employed, the software instructions may also be embodied in a non-transitory device that is being vended and/or provided, and that is not a transitory, propagating signal and/or a signal per se. For instance, the non-transitory device may be or include a hard disk drive, solid state drive, or CD ROM. Flash drives may also be used for storing the instructions. Additionally, the software code instructions may also be downloaded over the Internet (e.g., as part of an application (“app”) or software file). Accordingly, it is to be understood that although a software application for undertaking present principles may be vended with a device such as the system 100 described below, such an application may also be downloaded from a server to a device over a network such as the Internet. An application can also run on a server and associated presentations may be displayed through a browser (and/or through a dedicated companion app) on a client device in communication with the server.

Software modules and/or applications described by way of flow charts and/or user interfaces herein can include various sub-routines, procedures, etc. Without limiting the disclosure, logic stated to be executed by a particular module can be redistributed to other software modules and/or combined together in a single module and/ or made available in a shareable library. Also, the user interfaces (UI)/graphical UIs described herein may be consolidated and/or expanded, and UI elements may be mixed and matched between UIs.

Logic when implemented in software, can be written in an appropriate language such as but not limited to hypertext markup language (HTML)-5, Java®/JavaScript, C #or C++, and can be stored on or transmitted from a computer-readable storage medium such as a hard disk drive (HDD) or solid state drive (SSD), a random access memory (RAM), read-only memory (ROM), electrically erasable programmable read-only memory (EEPROM), a hard disk drive or solid state drive, compact disk read-only memory (CD-ROM) or other optical disk storage such as digital versatile disc (DVD), magnetic disk storage or other magnetic storage devices including removable thumb drives, etc.

In an example, a processor can access information over its input lines from data storage, such as the computer readable storage medium, and/or the processor can access information wirelessly from an Internet server by activating a wireless transceiver to send and receive data. Data typically is converted from analog signals to digital by circuitry between the antenna and the registers of the processor when being received and from digital to analog when being transmitted. The processor then processes the data through its shift registers to output calculated data on output lines, for presentation of the calculated data on the device.

Components included in one embodiment can be used in other embodiments in any appropriate combination. For example, any of the various components described herein and/or depicted in the Figures may be combined, interchanged or excluded from other embodiments.

The term “a” or “an” in reference to an entity refers to one or more of that entity. As such, the terms “a” or “an”, “one or more”, and “at least one” can be used interchangeably herein. “A system having at least one of A, B, and C” (likewise “a system having at least one of A, B, or C” and “a system having at least one of A, B, C”) includes systems that have A alone, B alone, C alone, A and B together, A and C together, B and C together, and/or A, B, and C together, etc.

The term “circuit” or “circuitry” may be used in the summary, description, and/or claims. The term “circuitry” includes all levels of available integration, e.g., from discrete logic circuits to the highest level of circuit integration such as VLSI, and includes programmable logic components programmed to perform the functions of an embodiment as well as processors (e.g., special-purpose processors) programmed with instructions to perform those functions.

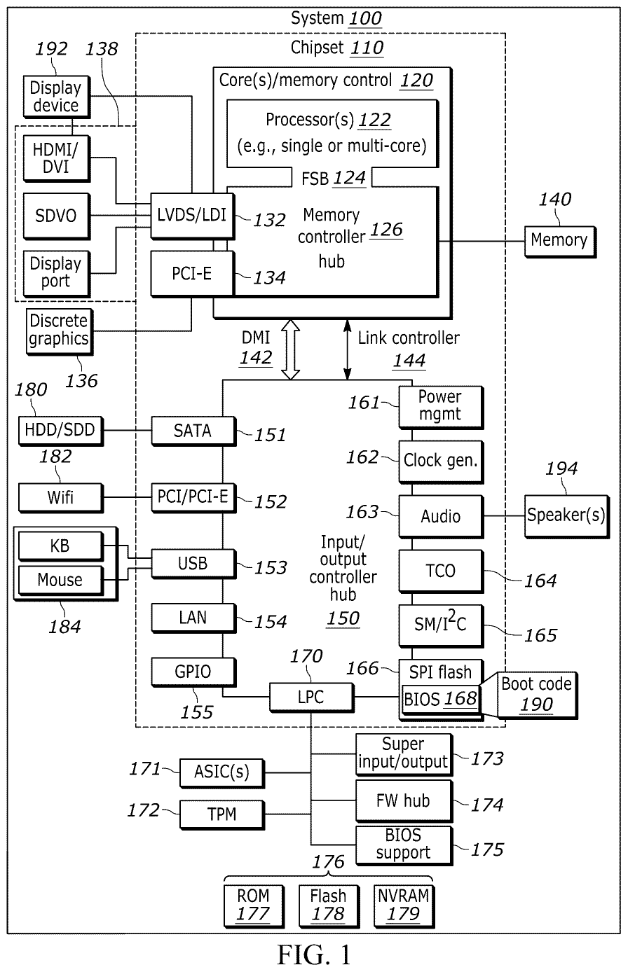

Now specifically in reference to FIG. 1, an example block diagram of an information handling system and/or computer system 100 is shown. Note that the system 100 may be housed within a computer chassis consistent with present principles.

In some embodiments, the system 100 may be a desktop computer system, such as one of the ThinkCentre®. The system 100 might also be a notebook computer system, such as ThinkPad® series of personal computers sold by Lenovo (US) Inc. of Morrisville, NC, or a workstation computer such as the ThinkStation® as sold by Lenovo (US) Inc. of Morrisville, NC; however, as apparent from the description herein, a client device, a server or other machine in accordance with present principles may include other features or only some of the features of the system 100. Also, the system 100 may be, e.g., a game console such as XBOX®, and/or the system 100 may include a mobile communication device such as a mobile telephone, notebook computer, and/or other portable computerized device.

As shown in FIG. 1, the system 100 may include a so-called chipset 110. A chipset refers to a group of integrated circuits, or chips, that are designed to work together. Chipsets are usually marketed as a single product (e.g., consider chipsets marketed under the brands INTEL®, AMD®, etc.).

In the example of FIG. 1, the chipset 110 has a particular architecture, which may vary to some extent depending on brand or manufacturer. The architecture of the chipset 110 includes a core and memory control group 120 and an I/O controller hub 150 that exchange information (e.g., data, signals, commands, etc.) via, for example, a direct management interface or direct media interface (DMI) 142 or a link controller 144. In the example of FIG. 1, the DMI 142 is a chip-to-chip interface (sometimes referred to as being a link between a “northbridge” and a “southbridge”).

The core and memory control group 120 includes a processor system 122 (e.g., one or more single core or multi-core processors, etc.) and a memory controller hub 126 that exchange information via a front side bus (FSB) 124. A processor system such as the system 122 may therefore include one or more processors acting independently or in concert with each other to execute an algorithm, whether those processors are in one device or more than one device. Additionally, as described herein, various components of the core and memory control group 120 may be integrated onto a single processor die, for example, to make a chip that supplants the “northbridge” style architecture.

The memory controller hub 126 interfaces with memory 140. For example, the memory controller hub 126 may provide support for DDR SDRAM memory (e.g., DDR, DDR2, DDR3, etc.). In general, the memory 140 is a type of random-access memory (RAM). It is often referred to as “system memory.”

The memory controller hub 126 can further include a low-voltage differential signaling interface (LVDS) 132. The LVDS 132 may be a so-called LVDS Display Interface (LDI) for support of a display device 192 (e.g., a CRT, a flat panel, a projector, a touch-enabled light emitting diode (LED) display or other video display, etc.). A block 138 includes some examples of technologies that may be supported via the LVDS interface 132 (e.g., serial digital video, HDMI/DVI, display port). The memory controller hub 126 also includes one or more PCI-express interfaces (PCI-E) 134, for example, for support of discrete graphics 136. For example, the memory controller hub 126 may include a 16-lane (x16) PCI-E port for an external PCI-E-based graphics card (including, e.g., one or more GPUs). An example system may thus include PCI-E for support of graphics.

In examples in which it is used, the I/O hub controller 150 can include a variety of interfaces. The example of FIG. 1 includes a SATA interface 151, one or more PCI-E interfaces 152 (optionally one or more legacy PCI interfaces), one or more universal serial bus (USB) interfaces 153, a local area network (LAN) interface 154 (more generally a network interface for communication over at least one network such as the Internet, a WAN, a LAN, a Bluetooth network using Bluetooth 5.0 communication, etc. under direction of the processor(s) 122), a general purpose I/O interface (GPIO) 155, a low-pin count (LPC) interface 170, a power management interface 161, a clock generator interface 162, an audio interface 163 (e.g., for speakers 194 to output audio), a total cost of operation (TCO) interface 164, a system management bus interface (e.g., a multi-master serial computer bus interface) 165, and a serial peripheral flash memory/controller interface (SPI Flash) 166, which, in the example of FIG. 1, includes basic input/output system (BIOS) 168 and boot code 190. With respect to network connections, the I/O hub controller 150 may include integrated gigabit Ethernet controller lines multiplexed with a PCI-E interface port. Other network features may operate independent of a PCI-E interface. Example network connections include Wi-Fi as well as wide-area networks (WANs) such as 4G and 5G cellular networks.

The interfaces of the I/O hub controller 150 may provide for communication with various devices, networks, etc. For example, where used, the SATA interface 151 and/or PCI-E interface 152 provide for reading, writing or reading and writing information on one or more drives 180 such as HDDs, SSDs or a combination thereof, but in any case the drives 180 are understood to be, e.g., tangible computer readable storage mediums that are not transitory, propagating signals. The I/O hub controller 150 may also include an advanced host controller interface (AHCI) to support one or more drives 180. The PCI-E interface 152 allows for wireless connections 182 to devices, networks, etc. The USB interface 153 provides for input devices 184 such as keyboards (KB), mice and various other devices (e.g., cameras, phones, storage, media players, etc.).

In the example of FIG. 1, the LPC interface 170 provides for use of one or more ASICs 171, a trusted platform module (TPM) 172, a super I/O 173, a firmware hub 174, BIOS support 175 as well as various types of memory 176 such as ROM 177, Flash 178, and non-volatile RAM (NVRAM) 179. With respect to the TPM 172, this module may be in the form of a chip that can be used to authenticate software and hardware devices. For example, a TPM may be capable of performing platform authentication and may be used to verify that a system seeking access is the expected system.

The system 100, upon power on, may be configured to execute boot code 190 for the BIOS 168, as stored within the SPI Flash 166, and thereafter processes data under the control of one or more operating systems and application software (e.g., stored in system memory 140). An operating system may be stored in any of a variety of locations and accessed, for example, according to instructions of the BIOS 168.

Additionally, though not shown for simplicity, in some embodiments the system 100 may include a gyroscope that senses and/or measures the orientation of the system 100 and provides related input to the processor system 122, an accelerometer that senses acceleration and/or movement of the system 100 and provides related input to the processor system 122, and/or a magnetometer that senses and/or measures directional movement of the system 100 and provides related input to the processor system 122.

Still further, the system 100 may include an audio receiver/microphone that provides input from the microphone to the processor system 122 based on audio that is detected, such as via a user providing audible input to the microphone. The system 100 may also include a camera that gathers one or more images and provides the images and related input (e.g., metadata like an image timestamp) to the processor system 122. The camera may be a thermal imaging camera, an infrared (IR) camera, a digital camera such as a webcam, a three-dimensional (3D) camera, and/or a camera otherwise integrated into the system 100 and controllable by the processor system 122 to gather still images and/or video.

Also, the system 100 may include a global positioning system (GPS) transceiver that is configured to communicate with satellites to receive/identify geographic position information and provide the geographic position information to the processor system 122. However, it is to be understood that another suitable position receiver other than a GPS receiver may be used in accordance with present principles to determine the location of the system 100.

It is to be understood that an example client device or other machine/computer may include fewer or more features than shown on the system 100 of FIG. 1. In any case, it is to be understood at least based on the foregoing that the system 100 is configured to undertake present principles.

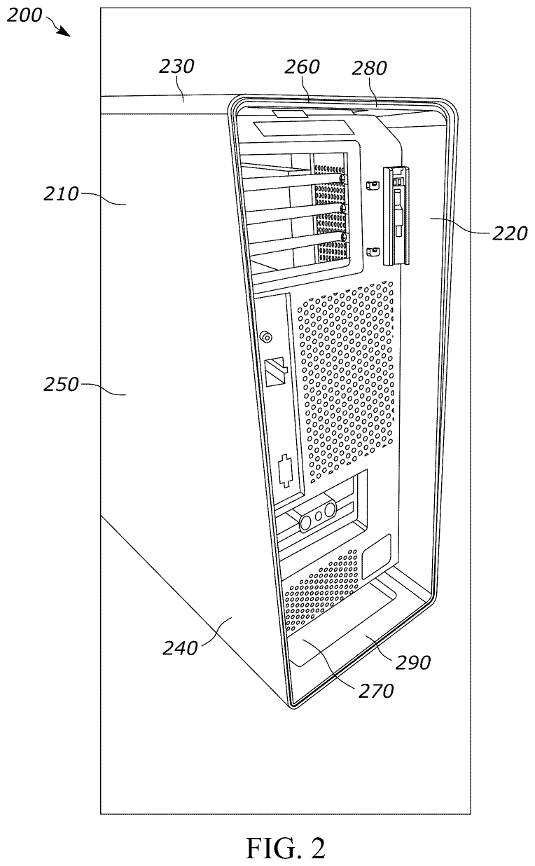

Turning now to FIG. 2, this figure shows a rear perspective view of a desktop/workstation computer 200 as housed within a rigid chassis 210. The chassis may be made of steel, aluminum alloy, mesh, tempered glass, acrylic, etc. It may be appreciated from FIG. 2 that the chassis 210 defines a rear opening 220 establishing a hollow rectangular prism, with the opening 220 being accessible via the rear of the chassis 210 due to the lack of an outer rear wall of the chassis 210.

FIG. 2 also shows that the top (horizontal) wall 230 of the chassis 210 and bottom (horizontal) wall 240 of the chassis 210 may each extend from front to back on the chassis 210 and may be bounded by a left (vertical) side wall 250 and right (vertical) side wall (not shown) of the chassis 210. The chassis 210 may also define a front wall not shown from the rear perspective view of FIG. 2.

Further note that the rear portions of the top wall 230 and bottom wall 240 have openings 260, 270 in their respective planes. The openings 260, 270 may therefore be adjacent to the rear opening 220 and establish handles 280, 290 at the rear of the chassis 210 for a user to grip the chassis 210 and move the chassis 210 about. In the present example, the openings 260, 270 are established by rectangular prisms with rounded corners, though the openings 260 may be formed by other shapes as well.

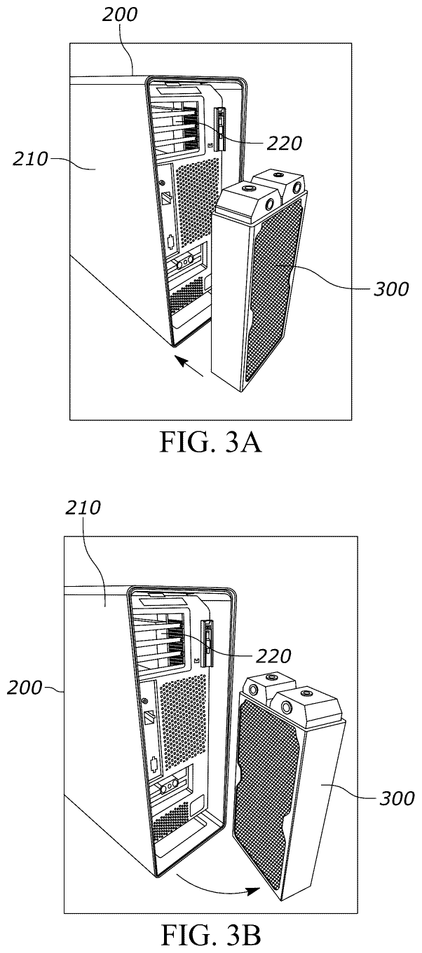

Turning to FIGS. 3A and 3B, these figures also show rear perspective views of the computer 200 and chassis 210, but this time in relation to a radiator 300 that is attachable to the rear of the chassis 210 to help cool internal components of the computer 200 via liquid cooling. It is to therefore be understood that the radiator 300 may establish a heat exchanger to dissipate heat from liquid, as circulating through the radiator 300, to the air external to the chassis 210 after the liquid has traveled through one or more hoses or other tubes running through the chassis 210 to absorb heat from the internal computing components.

It is to also be understood consistent with present principles that toggle clamps (not shown) may be used to establish hinges to mechanically attach the radiator 300 to the chassis 210 and also detach the radiator 300 therefrom. When attached, the radiator 300 may rotate between opened and closed positions about the hinge axis. While in the closed position, the radiator 300 may sit within the rear opening 220, and might even sit flush with the outer rear edges of the chassis 210. FIG. 3A therefore demonstrates that the radiator 300 may be positioned within the opening 220, while FIG. 3B demonstrates that the radiator 300, when coupled to the chassis 210 via the toggle clamps, may swing open about the hinge's axis of rotation for rear input output (I/O) access to the computing components within the chassis 210.

The toggle clamps will be described in greater detail in a moment. But first, it is to be understood that the toggle clamps may engage the chassis 210 directly to establish the hinges (e.g., without any intervening mounts or other components also being used to do so). Or, as is the case in certain example embodiments described below, the clamps may engage intervening, removable mounts that interface between the handles 280, 290 (and/or other rear portions of the chassis 210) and the toggle clamps.

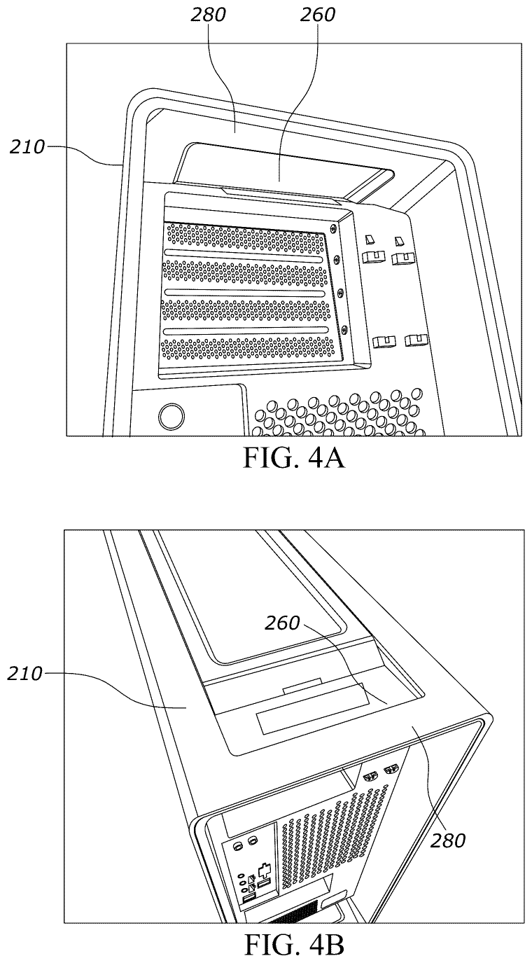

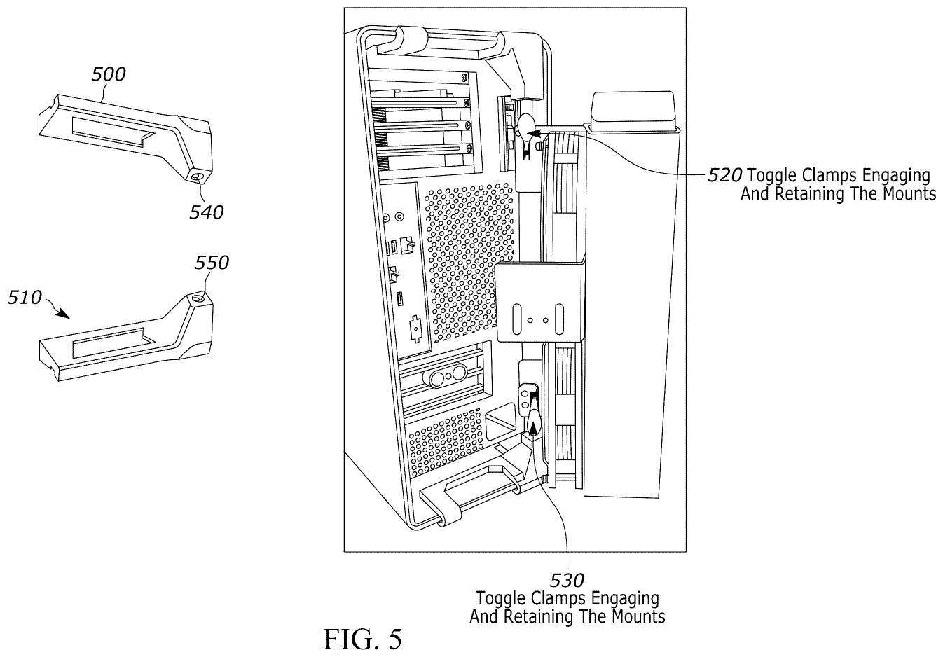

FIGS. 4A and 4B thus show respective lower and upper perspective views of the opening 260 and handle 280 of the chassis 210 for further illustration. FIG. 5 then shows upper and lower mounts 500, 510 that may be respectively inserted at least partially into the openings 260, 270 to couple to the handles 280, 290 so that the mounts 500, 510 can then interface with upper and lower toggle clamps 520, 530 to hingedly attach the radiator 300 to the chassis 210 (it being understood that the toggle clamps 520, 530 have already been attached to the radiator 300 itself). Thus, the toggle clamps 520, 530 may be transitioned to their fully extended position to attach the radiator 300 to the chassis 210, with the toggle clamps thus extending into cylindrical openings 540, 550 in the mounts 500, 510 to engage the mounts 500, 510 and retain the mounts 500, 510 on the chassis 210. Conversely, the toggle clamps 520, 530 may be transitioned to their retracted position to detach the radiator to the chassis 210.

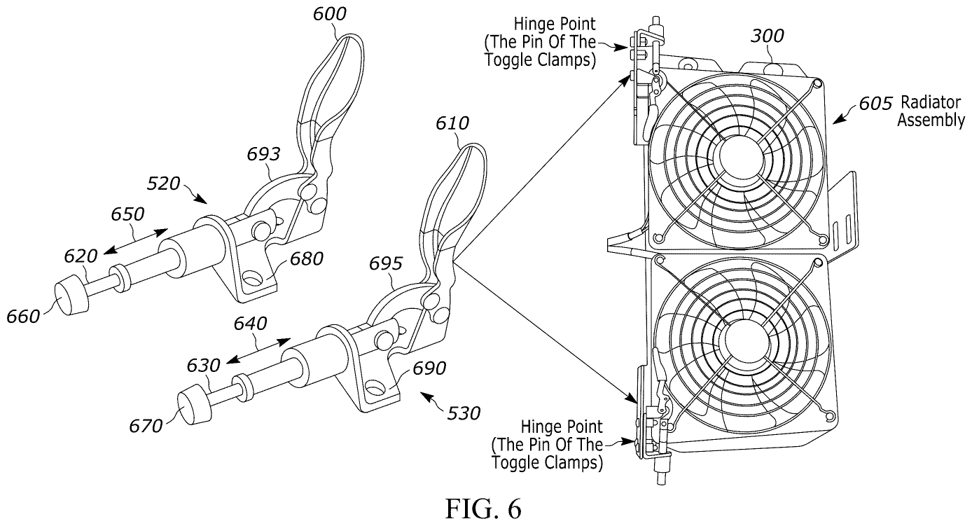

The left side of FIG. 6 shows the toggle clamps 520, 530 apart from the chassis 210 in perspective view. The right side of FIG. 6 shows the clamps 520, 530 in their fully retracted state as secured to the radiator 300 to establish a radiator/toggle clamp assembly 605. Per the left side of FIG. 6, the clamps 520, 530 are in between their extended and retracted states, while the right side of FIG. 6 shows the clamps 520, 530 in their retracted states.

Describing the clamps 520, 530 in even more detail, it may be appreciated from FIG. 6 that the toggle clamps 520, 530 have handles 600, 610 which may be made of metal along with a rubber exterior. Each handle 600, 610 may be radially movable about the respective clamp itself to transition the respective clamp between its extended and retracted states. Specifically, the handles 600, 610 may be movable to establish a clamp retracted position, in which case the handles 600, 610 might be oriented colinear or approximately colinear with the respective clamp's respective rigid, metal post 620, 630. The handles 600, 610 may also be movable to establish a clamp extended position, in which case the handles 600, 610 might be oriented obliquely forward to press up against a respective rigid clamp body 680,690 of the respective clamp. Thus, moving the handles 600, 610 to their extended positions moves the posts 620, 630 distally away from the handles 600, 610 along the longitudinal axes 640, 650 such that the posts 620, 630 extend farther away from the handles 600, 610. Conversely, moving the handles 600, 610 to their retracted positions moves the posts 620, 630 proximally toward the handles 600, 610.

FIG. 6 further demonstrates that, in some examples, the distal ends of the posts 620, 630 may terminate in wider cylindrical or frusto-conical rubber pads 660, 670. The pads 660, 670 may provide an interference fit with the inner walls of the openings 540, 550 when the posts 620, 630 extend into the openings 540, 550.

As also shown in FIG. 6 and mentioned above, the toggle clamps 520, 530 may include rigid clamp bodies 680, 690 through which the posts 620, 630 may move under control of the handles 600, 610. Also included on the toggle clamps 520, 530 may be respective circular plates 693, 695 to which proximal ends of the respective posts 620, 630 rotatably attach. The plates 693, 695 may also be attached to respective proximal ends of a respective handle 600, 610 (e.g., at an opposite side of the plate than where the respective post attaches). This configuration allows for the aforementioned radial movement of the handles 600, 610 to extend and retract the posts 620, 630 linearly along the axes 640, 650 and through openings in the clamp bodies 680, 690. Also note that the right side of FIG. 6 shows the clamp bodies 680, 690 as secured (e.g., mounted) to a left side of the radiator 300 via screws or other fasteners to create hinge points at the posts 620, 630 (e.g., “pins”) of the toggle clamps 520, 530.

With the description of FIG. 6 in mind, now refer back to FIG. 5. It may be appreciated per FIG. 5 that with the toggle clamps 520, 530 mounted to the radiator 300 using fasteners extending through the clamp bodies 680, 690 and into the radiator 300, and with the distal end portions of the posts 620, 630 positioned outside of the cylindrical hollow openings 540, 550 but still coaxially with the openings 540, 550, the handles 600, 610 may be moved radially to their extended positions for the posts 620, 630 to extend into the openings 540, 550 and engage the mounts 500, 510. This configuration both locks the mounts 500, 510 onto the handles 280, 290, and also mounts the radiator 300 onto the chassis 210 through the toggle clamps'engagement with the mounts 500, 510 themselves. Thus, the radiator 300 is hingedly coupled to the chassis 210 to rotate in and out of the rear opening 220 on the chassis 210, establishing a vertical axis of rotation for the radiator 300 along the rear of the right sidewall of the chassis 210 via the hinge.

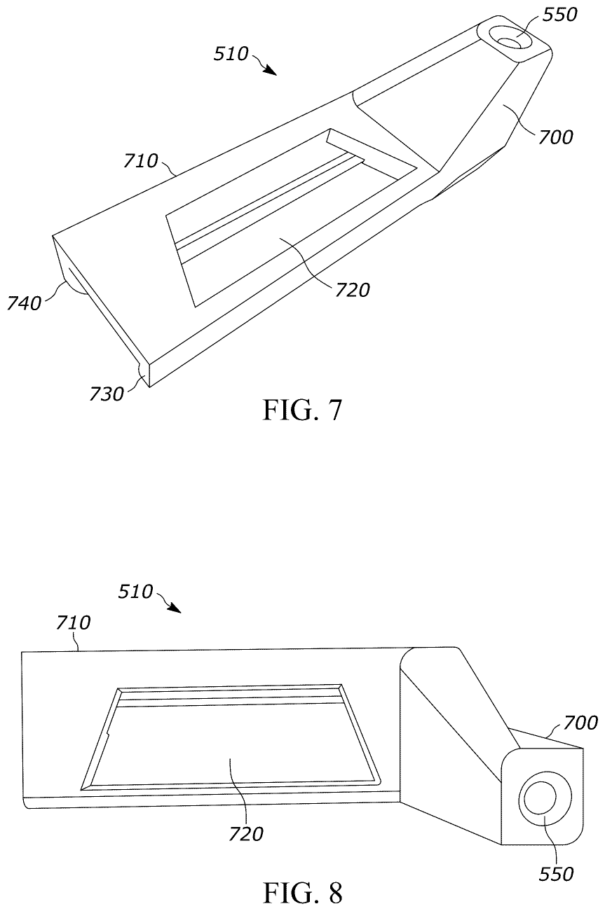

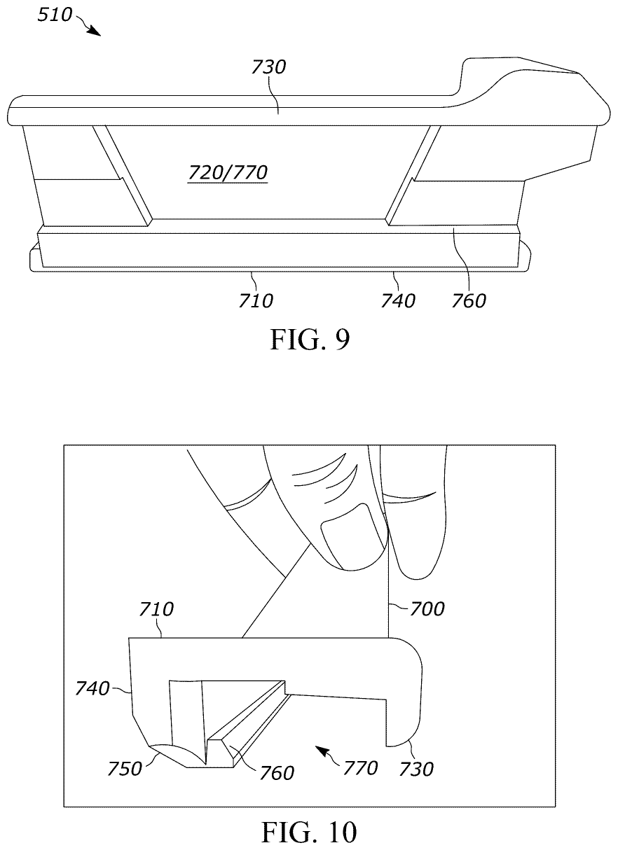

The lower mount 510 mentioned above will now be described in greater detail in reference to FIGS. 7-10, with it being understood that the upper mount 500 may be similarly configured. FIG. 7 shows an angled upper perspective view of the mount 510, FIG. 8 shows a top perspective view of the mount 510, FIG. 9 shows a bottom perspective view of the mount 510, and FIG. 10 shows a side perspective view of the mount 510.

As shown in these figures, the rigid mount 510 may be formed as an integral single component created through injection molding, three-dimensional (3D) printing, computer numerical control (CNC) manufacturing, and/or other methods. The mount 510 may be made of a plastic or other polymer, though still other materials may also be used. Also note here that the chassis 210 may be similarly integral and itself created through one of the above-mentioned processes.

These figures also show that the hollow cylindrical opening (e.g., chamber) 550 is formed in a leg 700 of the mount 510. The leg 700 defines a front wall in a plane that is orthogonal to a primary plane of an elongated body 710 of the mount 510. The leg 700 also defines a rear wall that faces inward toward the chassis 210 when the mount 510 is installed thereon. The rear wall slopes obliquely outward as it extends proximally toward the body 710. The sidewalls of the leg 700 may also be orthogonal to the primary plane of the body 710 and orthogonal to the plane established by the front wall of the leg 700. The distal end surface of the leg 700, which provides access to the opening 550, may be flat and establish a plane that is orthogonal to the planes of the front and side walls of the leg 700.

Note that other configurations for the leg 700 are also possible. For example, the inner (proximal) sidewall of leg 700 may also be obliquely oriented to slope inward as it extends distally, while the outer (distal) sidewall of the leg 700 may nonetheless remain flat and not slope to therefore meet and sit flush against the flat inner surface of the chassis 210 at the rear opening 220. And regardless of whether one or more of the sidewalls are oriented obliquely with respect to the primary plane of the body 710 or not, in certain examples the distal end portion of the leg 700 that bears the cylindrical opening 550 may be shaped as a cube or rectangular prism, with oblique portions of the leg walls extending proximally toward the body 710 from the proximal end of the cube or rectangular prism-shaped portion. In addition, in some examples the mouth of the opening 550 may be frusto-conical in shape, sloping inward distally to proximally before giving way to a cylindrical hollow portion farther inside the leg 700.

Now describing the body 710 in greater detail, the body 710 may include an opening 720 for ergonomic gripping by a user. As shown best in FIG. 8, the opening 720 may be trapezoid-shaped in the primary (X-Y) plane of the body 710 while also extending through the body 710 in the Z dimension. The side walls of the trapezoid may slope, in the X-Y plane, inward distally to proximally as shown in FIG. 8 (e.g., away from the front/outer portion of the mount 510 that faces away from the chassis 210). In the Z-dimension, the inner sidewalls of the body 710 that help define the opening 720 may be orthogonal to the X-Y plane, or may slope inward or outward.

The bottom face of the body 710—the face opposite the one from which the leg 700 extends—may include additional structural features for attaching the mount 710 to the handle 290. Specifically, FIGS. 9 and 10 show that the mount 710 may include opposing legs 730, 740 extending in the Z dimension away from the body 710. Both legs 730, 740 may also extend the entire width of the body 710.

The leg 730 may also include inner and outer walls that are flat as extending orthogonally in the Z dimension away from the body 710. In contrast, the leg 740 may begin with flat portions extending orthogonally away from the body 710 before the outer sidewall begins extending obliquely inward at a lower wall portion 750 to meet an inner ridge 760 formed on the distal end portion of the inner wall of the leg 740. The ridge 760 may extend the entire width of the leg 740/body 710.

Describing the ridge 760 in even more detail, as shown in FIG. 10, the ridge 760 may include a flat (horizontal) wall that is proximal to the body 710 and parallel to the primary plane of the body 710. The ridge 760 may also include an inner wall that slopes obliquely downward and inward as it extends more centrally into the opening 770 created between the legs 730, 740, with the opening 770 connected to the opening 720. This allows the handle 290 to be positioned within the opening 770, with the mount 510 positioned at an angle to first engage the ridge 760 with the proximal (inner) wall of the handle 290 to hook onto it. The mount 510 may then be rotated so that the body 710 sits flush against the inner (horizontal) X-Y surface of the handle 290, which brings the leg 730 into contact with the distal (outer) wall of the handle 290.

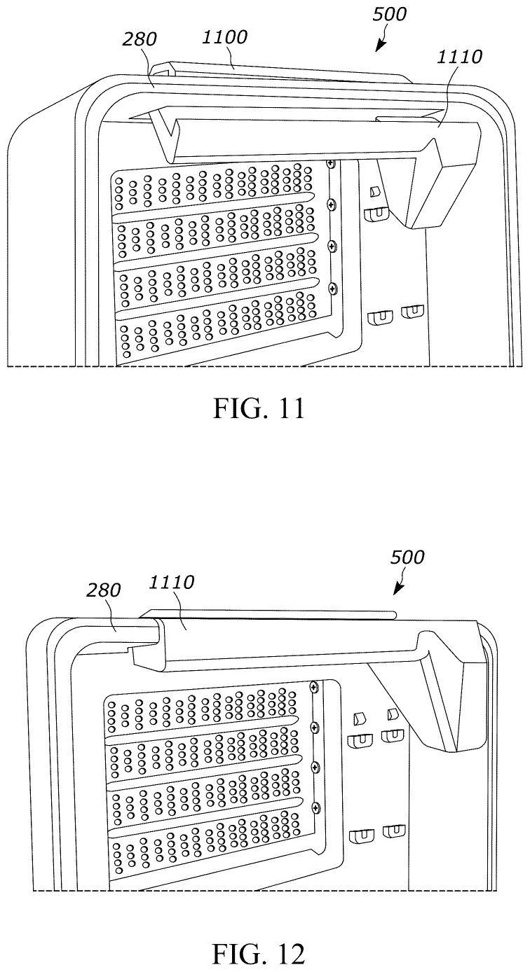

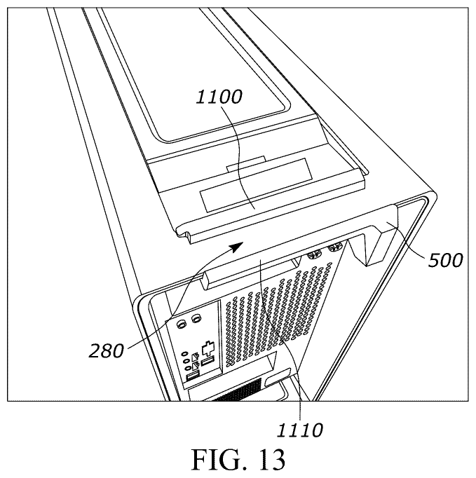

FIG. 11 therefore shows the first part of this engagement action in perspective view, while FIGS. 12 and 13 show the second part of this engagement action in perspective view. Note that these views actually show the mount 500 as engaged with the upper handle 280, with it being reiterated that the mount 500 may be similar in structure and configuration to the mount 510.

As shown in FIG. 11, a ridge 1100 of the mount 500 (that is similar to the ridge 760 of the mount 510) has been positioned to wrap around the inner wall of the handle 280 and up onto the top X-Y surface of the handle 280 to hook onto the handle 280. Per FIG. 11, one degree of freedom is afforded as the mount 500 may still swing downward about the pivot point created by the ridge 1100/handle 280 interface.

Then as shown in FIGS. 12 and 13, the mount 500 may be subsequently swung up for the opposing leg 1110 of the mount 500 (that is similar to the leg 730 of the mount 510) to meet the handle 280. The leg 1110 may then engage the outer wall of the handle 280. In some examples, this may be due to an interference/friction fit between the two components to couple the mount 500 to the handle 280, with the mount 500 gripping onto the handle 280 via the ridge 1100 that wraps around the handle 280.

Then with the mount 500 so positioned, and the mount 510 similarly positioned on the lower handle 290, the combined radiator/toggle clamp assembly 605 as shown on the right side of FIG. 6 may be engaged with the mounts 500, 510 as described above to couple (e.g., mount) the assembly 605 onto the chassis 210. This enables subsequent rotation of the assembly 605 about the hinge established by the toggle clamps 520, 530 as extending into the openings 540, 550 on the mounts 500, 510.

Moving on from FIGS. 12 and 13, it is to be understood that although chassis openings and handles have been described above as being located on top and bottom horizontal surfaces of the chassis 210, they might additionally or alternatively be located at upper or lower portions of the sidewalls of the chassis 210. In such instances, the axis of rotation of the added component (e.g., radiator) may be rotated ninety degrees, with like mounts being used, or the openings in the mounts may be altered to still maintain a vertical axis of rotation as described above.

It is to be further understood that present principles may be applied to embodiments where the chassis being used is not one for housing a computer, but instead one for housing other types of items. For example, the chassis might be a vehicle chassis, a furniture chassis, or other type of chassis. In addition, toggle clamp hinges as disclosed herein may also be used for swinging doors, windows, and other items without using a chassis per se, such as using toggle clamp hinges for the door of a cabinet or walk-through door in a building.

It may now be appreciated based on the foregoing description that two push-pull toggle clamps may be provided as a kit with other components, and which may be used as quick disconnect hinges to provide a single mechanism to supply both an axis of rotation and a clamping force that extends parallel to the axis of rotation. This permits the installation and removal of a radiator which mates with thermal components within the workstation computer 200. The clamping force is applied to the handle of the workstation chassis via mountable hinge pieces (e.g., the mounts 500, 510), which are also rigidly affixed to the chassis due to the clamping force. This allows for the attaching of a radiator to the workstation computer's chassis as that chassis is already manufactured so that additional modifications to the chassis need not be undertaken to accommodate the additional attachment of the radiator itself.

Components included in one embodiment can be used in other embodiments in any appropriate combination. For example, any of the various components described herein and/or depicted in the Figures may be combined, interchanged or excluded from other embodiments.

It is to be understood that whilst present principles have been described with reference to some example embodiments, these are not intended to be limiting, and that various alternative arrangements may be used to implement the subject matter claimed herein. Accordingly, while particular techniques and devices are herein shown and described in detail, it is to be understood that the subject matter which is encompassed by the present application is limited only by the claims.

What is claimed is:

1. An apparatus, comprising:
a computer chassis comprising a first opening at an upper portion of the computer chassis and comprising a second opening at a lower portion of the computer chassis;
a first toggle clamp for coupling to the computer chassis via the first opening;
a first mount for coupling the first toggle clamp to the computer chassis via the first opening;
a second toggle clamp for coupling to the computer chassis via the second opening;
a second mount for coupling the second toggle clamp to the computer chassis via the second opening; and
at least one computer-related component to which the first and second toggle clamps are couplable for the at least one computer-related component to rotate about a hinge established by the first and second toggle clamps as coupled to the computer chassis.

2. The apparatus of claim 1, wherein the coupling of the first toggle clamp to the computer chassis via the first mount and the coupling of the second toggle clamp to the computer chassis via the second mount establish a vertical axis of rotation for the at least one computer-related component to rotate about the hinge.

3. The apparatus of claim 1, wherein the upper and lower portions of the computer chassis are adjacent to the rear of the computer chassis.

4. The apparatus of claim 1, wherein the at least one computer-related component comprises a radiator.

5. The apparatus of claim 1, comprising a personal computer housed within the computer chassis.

6. The apparatus of claim 1, wherein the first and second openings define respective first and second handles of the computer chassis.

7. The apparatus of claim 6, wherein the first mount is configured to attach to the first handle, and wherein the second mount is configured to attach to the second handle.

8. The apparatus of claim 1, wherein the first mount comprises a third opening into which a first post of the first toggle clamp is extendable to couple the first toggle clamp to the computer chassis with the first mount already engaged with the computer chassis, and wherein the second mount comprises a fourth opening into which a second post of the second toggle clamp is extendable to couple the second toggle clamp to the computer chassis with the second mount already engaged with the computer chassis.

9. The apparatus of claim 8, wherein the first toggle clamp is manipulable to place the first toggle clamp into an extended position in which the first post extends into the third opening, and wherein the second toggle clamp is manipulable to place the second toggle clamp into an extended position in which the second post extends into the fourth opening.

10. An apparatus, comprising:
a chassis comprising a first opening and comprising a second opening;
a first toggle clamp for coupling to the chassis via the first opening;
a first mount for coupling the first toggle clamp to the chassis via the first opening;
a second toggle clamp for coupling to the chassis via the second opening; and
a second mount for coupling the second toggle clamp to the chassis via the second opening.

11. The apparatus of claim 10, comprising:
at least one component to which the first and second toggle clamps are couplable for the at least one component to rotate about a hinge established by the first and second toggle clamps as coupled to the chassis.

12. The apparatus of claim 10, wherein the chassis is a computer chassis.

13. The apparatus of claim 1, wherein the first mount comprises a third opening into which a first post of the first toggle clamp is extendable to couple the first toggle clamp to the chassis with the first mount already engaged with the chassis, and wherein the second mount comprises a fourth opening into which a second post of the second toggle clamp is extendable to couple the second toggle clamp to the chassis with the second mount already engaged with the chassis.

14. The apparatus of claim 13, wherein the first toggle clamp is manipulable to place the first toggle clamp into an extended position in which the first post extends into the third opening, and wherein the second toggle clamp is manipulable to place the second toggle clamp into an extended position in which the second post extends into the fourth opening.

15. A kit, comprising:
a first mount for coupling a first clamp to a chassis via a first opening on the chassis to establish part of a hinge;
the first clamp;
a second mount for coupling a second toggle clamp to the chassis via a second opening to establish part of the hinge; and
the second clamp.

16. The kit of claim 15, comprising:
the chassis.

17. The kit of claim 16, comprising:
a computer housed within the chassis.

18. The kit of claim 15, wherein the first clamp and the second clamp are toggle clamps.

19. The kit of claim 15, comprising:
at least one component to which the first and second clamps are couplable for the at least one component to rotate about the hinge established by the first and second clamps as coupled to the chassis.

20. The kit of claim 19, wherein the at least one component comprises a radiator.
